(19) United States
(12) Patent Application Publication
(10) Pub. No.: US 2008/0159010 A1
(43) Pub. Date: Jul. 3, 2008

(54) Multi-use eFuse Macro

(76) Inventors: Tarl S. Gordon, Leander, TX (US); Mack W. Riley, Austin, TX (US)

Correspondence Address: IBM CORPORATION- AUSTIN (JVL);C/O VAN LEEUWEN & VAN LEEUWEN, PO BOX 90609, AUSTIN, TX, 78709-0609, US

(21) Appl. No.: 12/049,307

(22) Filed: Mar. 15, 2008

Related U.S. Application Data
(63) Continuation of application No. 11/245,299, filed on Oct. 6, 2005.

(51) Int. Cl. G11C 7/10

(52) U.S. Cl. 365/189.02

(57) ABSTRACT

A multi-use eFuse macro is presented. A device includes multiplexers and selection logic that allow eFuse latches to store auxiliary data in addition to programming electronic fuses. The multiplexers and selection logic are coupled to the inputs and outputs of the eFuse latches, and are controlled by a processing unit or an external tester. When a tester wishes to program or update an eFuse element (electronic fuses), the multiplexers and selection logic are configured for “eFuse” mode, which allows an eFuse controller to provide program data and control data to the eFuse latches which, in turn, program the eFuse element. When the device requires additional storage, the multiplexers and selection logic are configured for “auxiliary data” mode, which allows a processing unit to store and retrieve data in the eFuse latches.

### RELATED APPLICATIONS

This application is a continuation application of co-pending U.S. Non-Provisional patent application Ser. No. 11/245,299, entitled “System and Method for Multi-use eFuse Macro,” filed on Oct. 6, 2005.

### BACKGROUND OF THE INVENTION

1. Technical Field

The present invention relates to system and method for a multi-use eFuse macro. More particularly, the present invention relates to a system and method for configuring multiplexers and selection logic to store auxiliary data in eFuse latches in addition using the eFuse latches to program electronic fuses.

2. Description of the Related Art

As technology advances, new process and design techniques extend design possibilities while, at the same time, limit older technology reuse, which is the case for metal fuses. Historically, metal fuses were used to store customized data and provide repair solutions for silicon defects. Metal fuses required little area relative to overall device area and were mechanically programmed using a laser. Today, metal fuses require a significantly greater proportion of a device's area because they cannot scale with device technology due minimum sizing requirements for laser programming. Metal fuses also require a direct “line-of-sight” view for the laser, which complicates physical design methodologies because they may not be placed underneath overlying power busses.

The development of an electrically programmed fuse, or “eFuse,” has resolved many issues relating to metal fuses. The eFuse is manufactured as a polysilicon link and is significantly smaller than the metal fuse. It can also shrink in size with device technology as a process evolves because the eFuse has fewer mechanical dependencies. In addition, since an eFuse is electrically programmed, it is not required to be viewable by a laser and, therefore, may be placed underneath overlying power buses.

An eFuse “macro” includes an eFuse “element” and eFuse “latches.” The eFuse element includes electronic fuses and the eFuse latches include a program solution latch and a program enable/data capture latch. The eFuse latches receive program data and control data from an eFuse controller, and provide the program data and control data to the eFuse element, which programs the electronic fuses. A challenge found is that a device uses the eFuse latches during eFuse element programming, but, during other device mode operations, the eFuse latches go unused, which results in wasted resources.

What is needed, therefore is a system and method to effectively utilize the eFuse latches when they are not programming or updating an eFuse element.

### SUMMARY

It has been discovered that the aforementioned challenges are resolved using a system and method for configuring multiplexers and selection logic to store auxiliary data in eFuse latches in addition using the eFuse latches to program electronic fuses. Multiplexers and selection logic are coupled to the inputs and outputs of the eFuse latches, respectively, and are controlled by a processing unit or an external tester via a multiplexer control signal. When a tester wishes to program or update an eFuse element, the multiplexers and selection logic are configured for “eFuse” mode, which allows an eFuse controller to provide program data and control data to the eFuse latches which, in turn, program the eFuse element. When the device requires additional storage, the multiplexers and selection logic are configured for “auxiliary data” mode, which allows a processing unit to store and retrieve data in the eFuse latches.

An efuse macro includes an eFuse element, and two eFuse latches, which are a program solution latch and a program enable/data capture latch. The eFuse element includes multiple electronic fuses for programming. The program solution latch and the program enable/data capture latch include multiple latches for staging eFuse program data and eFuse control data that, in turn, programs the eFuse element.

When a device is in an “eFuse” mode, such as when programming or updating the eFuse element, the multiplexer control signal instructs input multiplexers to select eFuse program data and eFuse control data from an eFuse controller as their inputs. In turn, one multiplexer provides the eFuse program data to the program solution latch, and the other multiplexer provides the eFuse control data to the program enable/data capture latch. The multiplexer control signal may also control the selection logic. In eFuse mode, the multiplexer control signal configures the selection logic to provide the eFuse latches' output to the eFuse controller, which passes it to a tester that verifies the eFuse element's programming. In one embodiment, a processing unit controls the multiplexer control signal. In another embodiment, an external tester controls the multiplexer control signal through the eFuse controller.

When the device is not in eFuse mode and, instead, is in “auxiliary data” mode, a device may use the program solution latch and the program enable/data capture latch to store auxiliary data. For example, the device may be operational and wish to store device level configuration ring information in the eFuse latches in order to verify configuration data content at a later time.

In auxiliary data mode, the multiplexer control signal configures the multiplexers to select auxiliary data as their inputs. In turn, the multiplexers provide auxiliary data from a processing unit to the program solution latch and the program enable/data capture latch which, as a result, store the auxiliary data for later retrieval. The multiplexer control signal may also configure the selection logic and, in auxiliary data mode, configures the selection logic to provide the eFuse latches' output (i.e. auxiliary data) to the processing unit.

The foregoing is a summary and thus contains, by necessity, simplifications, generalizations, and omissions of detail; consequently, those skilled in the art will appreciate that the summary is illustrative only and is not intended to be in any way limiting. Other aspects, inventive features, and advantages of the present invention, as defined solely by the claims, will become apparent in the non-limiting detailed description set forth below.

### BRIEF DESCRIPTION OF THE DRAWINGS

The present invention may be better understood, and its numerous objects, features, and advantages made apparent to those skilled in the art by referencing the accompanying drawings.

FIG. 1 is a high level diagram showing eFuse macros and an eFuse controller in a device;

FIG. 2 is a diagram showing an eFuse macro that includes an eFuse element and eFuse latches;

FIG. 3 is a diagram showing multiplexers and selection logic coupled to eFuse latches, which allows a device to use the eFuse latches to store auxiliary data;

FIG. 4 is a diagram showing an external test system controlling data flow to eFuse latches during eFuse element programming;

FIG. 5 is a flowchart showing steps taken in configuring multiplexers to select eFuse data or auxiliary data as inputs to provide to eFuse latches;

FIG. 6 is a block diagram of a computing device capable of implementing the present invention; and

FIG. 7 is another block diagram of a computing device capable of implementing the present invention.

### DETAILED DESCRIPTION

The following is intended to provide a detailed description of an example of the invention and should not be taken to be limiting of the invention itself. Rather, any number of variations may fall within the scope of the invention, which is defined in the claims following the description.

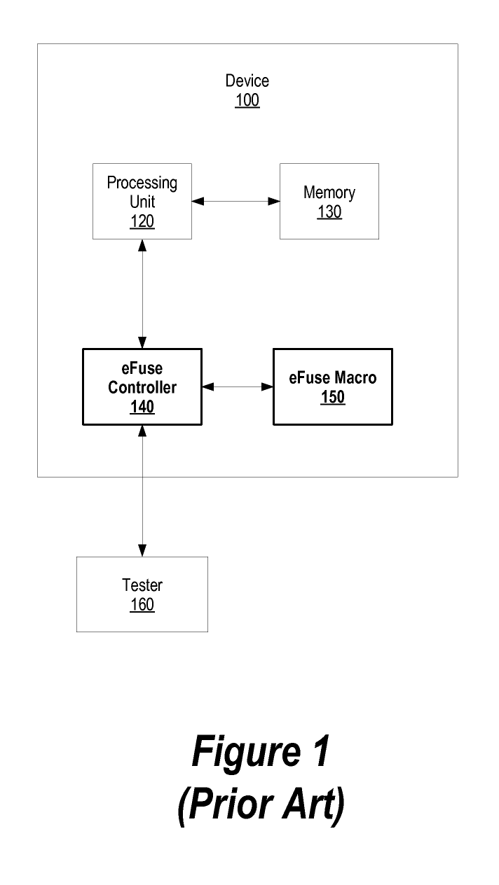

FIG. 1 is a high level diagram showing eFuse macros and an eFuse controller in a device. FIG. 1 shows device 100 that includes processing unit 120, memory 130, eFuse controller 140, and eFuse macro 150. Processing unit 120 includes a processing core, such as a digital signal processor, a microcontroller, or a microprocessor. Memory 130 is memory internal to device 100, such as L2 memory.

EFuse controller 140 and eFuse macro 150 work in conjunction with each other to provide device 100 with electronic fusing capability. For example, when tester 160 tests device 100 and identifies defects on device 100, such as areas within memory 130 that are not functioning, tester 160 sends program data and control data to eFuse controller 140 corresponding to the defects. Continuing with this example, eFuse controller 140 uses the program data and control data to program electronic fuses (eFuse element) included in eFuse macro 150 in order to repair the identified defects.

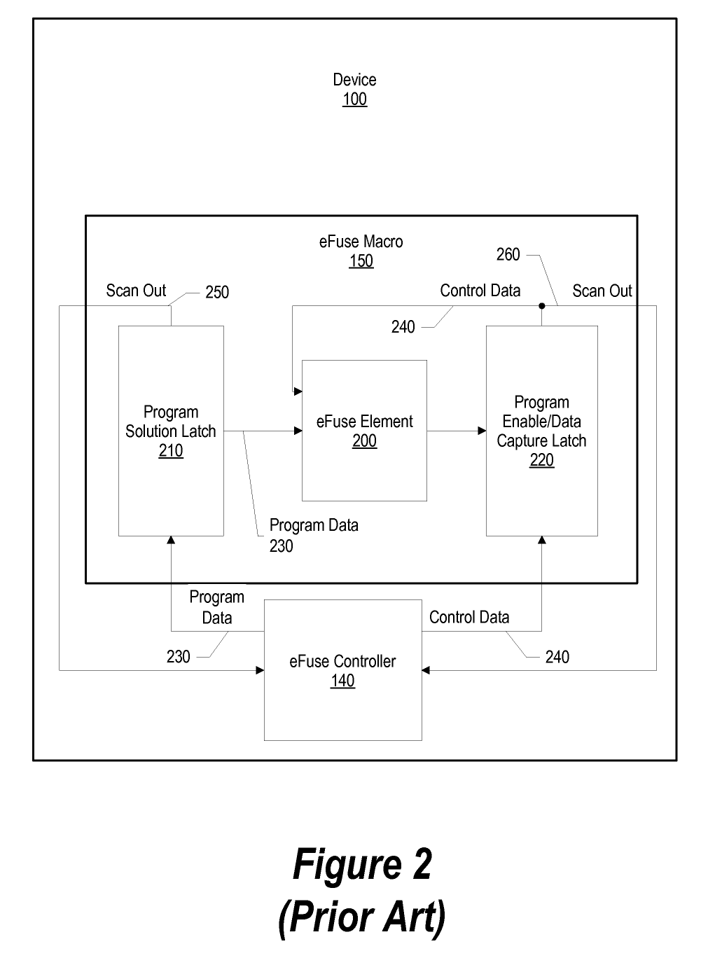

During the programming, eFuse controller 140 provides the program data and control data to eFuse “latches” included in eFuse macro 150, which then program an eFuse “element” that includes electronic fuses (also included in eFuse macro 150, see FIG. 2 and corresponding text for further details regarding eFuse latches and eFuse elements). Without the invention described herein, once eFuse controller 140 programs the eFuse element, device 100 does not use the eFuse latches afterwards during normal operation.

FIG. 2 is a diagram showing an eFuse macro that includes an eFuse element and eFuse latches. FIG. 2 shows device 100, eFuse macro 150, and eFuse controller 140, which are the same as that shown in FIG. 1. EFuse macro 150 includes eFuse element 200, and two eFuse latches, which are program solution latch 210 and program enable/data capture latch 220. EFuse element 200 includes multiple electronic fuses for programming. Program solution latch 210 and program enable/data capture latch 220 both include multiple latches for use in storing program data and control data that, in turn, programs eFuse element 200.

When eFuse controller 140 wishes to program the electronic fuses in eFuse element 200, eFuse controller 140 sends program data 230 to program solution latch 210 and sends control data 240 to program enable/data capture latch 220. In turn, program solution latch 210 provides program data 230 to eFuse element 200, and program enable/data capture latch 220 provides control data 240 to eFuse element 200. Program data 220 and control data 240 are used in conjunction with each other to program particular fuses included in eFuse element 200. Tester 160 receives scan out 250 and scan out 260 from the eFuse latches (through eFuse controller 140) in order to verify eFuse element 200's programming. As discussed previously, without the invention described herein, once eFuse controller 140 programs eFuse element 200, device 100 does not use program solution latch 210 and program enable/data capture latch 220 during normal operation, which results in wasted resources.

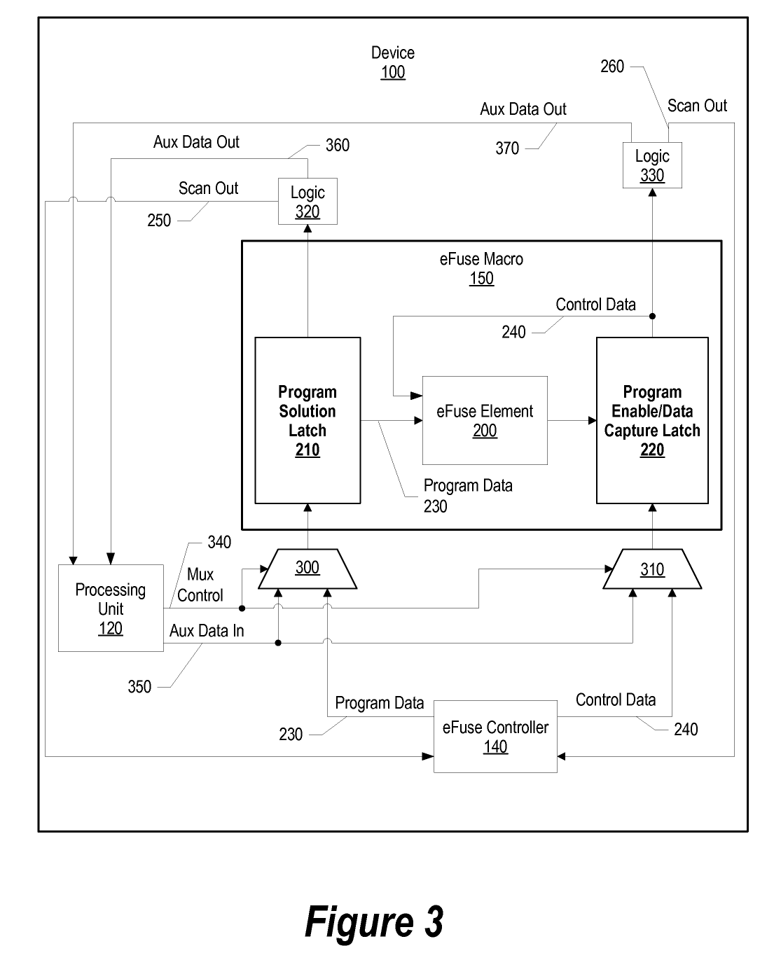

FIG. 3 is a diagram showing multiplexers and selection logic coupled to eFuse latches, which allows a device to use the eFuse latches to store auxiliary data. FIG. 3 includes device 100, eFuse controller 140, eFuse macro 150, program solution latch 210, program enable/data capture latch 220, and eFuse element 200, each of which are the same as that shown in FIG. 2. FIG. 3 also includes multiplexers 300-310 and selection logic 320-330 that are coupled to the inputs and outputs of program solution latch 210 and program enable/data capture latch 220. Multiplexers 300-310 and selection logic 320-330 allow device 100 to use the eFuse latches to 1) program eFuse element 200 as usual, and 2) use the eFuse latches to store auxiliary data.

Processing unit 120 is the same as that shown in FIG. 1, and includes multiplexer control logic or software code that controls input multiplexers 300 and 310 via multiplexer control 340. When device 100 is in an “eFuse” mode, such as when programming or updating eFuse element 200, multiplexer control 340 instructs multiplexers 300 and 310 to select program data 230 and control data 240, respectively, as its inputs. In turn, multiplexer 300 provides program data 230 to program solution latch 210, and multiplexer 310 provides control data 240 to program enable/data capture latch 220.

Multiplexer control 340 may also control selection logic 320 and 330, which is not shown in FIG. 3 for simplicity sake. In eFuse mode, processing unit 120 configures selection logic 320 to provide program solution latch 210's output to eFuse controller 140 via scan out 250, and configures selection logic 330 to provide program enable/data capture latch 220's output to eFuse controller 140 via scan out 260. In turn, eFuse controller 140 sends scan out 250 and 260 a test system for verifying eFuse element 200's programming.

When device 100 is not in eFuse mode and, instead, is in “auxiliary data” mode, processing unit 120 uses program solution latch 210 and program enable/data capture latch 220 to store auxiliary data. For example, device 100 may be operational and wish to store device level configuration ring information in the eFuse latches in order to verify configuration data content at a later time.

In auxiliary data mode, processing unit 120 instructs (via multiplexer control 340) multiplexers 300 and 310 to select auxiliary data in 350 as their inputs. In turn, multiplexers 300 and 310 provide auxiliary data in 350 to program solution latch 210 and program enable/data capture latch 220, respectively, which the latches store for later retrieval by processing unit 120.

As discussed above, multiplexer control 340 may be connected to selection logic 320 and 330. In auxiliary data mode, processing unit 120 configures selection logic 320 to provide program solution latch 210's output to processing unit 120 via auxiliary data out 360, and configures selection logic 330 to provide program enable/data capture latch 220's output to processing unit 120 via auxiliary data out 370.

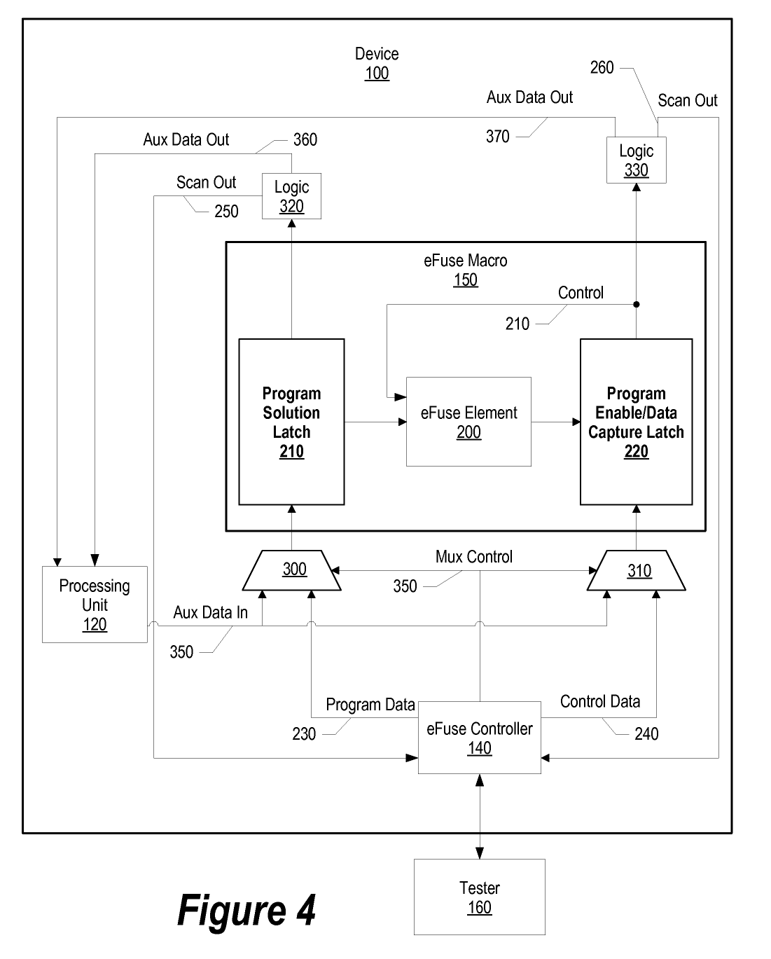

The embodiment shown in FIG. 3 shows processing unit 120 controlling the multiplexers to select a particular input or provide a particular output. In one embodiment, multiplexers 300-310 and selection logic 320-330 are placed in an “auxiliary data” mode by default, and change configurations to eFuse mode when eFuse controller 140 wishes to program or update eFuse element 200. In another embodiment, multiplexers 300-310 and selection logic 320-330 are controlled by an external component, such as a test system (see FIG. 4 and corresponding text for further details regarding external multiplexer control).

FIG. 4 is a diagram showing an external test system controlling data flow to eFuse latches during eFuse element programming. FIG. 4 is similar to FIG. 3 with the exception that test system 160 instructs eFuse controller 140 as to when to configure multiplexers 300-310 and selection logic 320-330 for eFuse mode. Tester 160 is the same as that shown in FIG. 1.

In one embodiment, tester 160 may use one of device 100's external pins to inform eFuse controller 140 to go into “eFuse” mode (e.g. pull low). When in eFuse mode, eFuse controller 140 uses multiplexer control 350 to instruct multiplexers 300 and 310 to select program data 230 and control data 240, respectively to feed into their respective eFuse latches and thus, program or update eFuse element 200. In this embodiment, once device 100 decouples from tester 160, device 100 reverts back to auxiliary data mode, and eFuse controller 140 instructs multiplexers 300 and 310 to select auxiliary data in 350. As such, processing unit 120 may use program solution latch 210 and program enable/data capture latch 220 to store data. Multiplexer control 350 may also configure selection logic 320 and 330 for eFuse mode or auxiliary data mode as discussed in FIG. 3.

In another embodiment, tester 160 may send a mode bit to eFuse controller 140, which instructs eFuse controller 140 to configure the multiplexers in eFuse mode. In this embodiment, when tester 160 is finished programming or updating eFuse element 200, tester 160 sends another mode bit to eFuse controller 140, which instructs eFuse controller 140 to configure the multiplexers in auxiliary data mode.

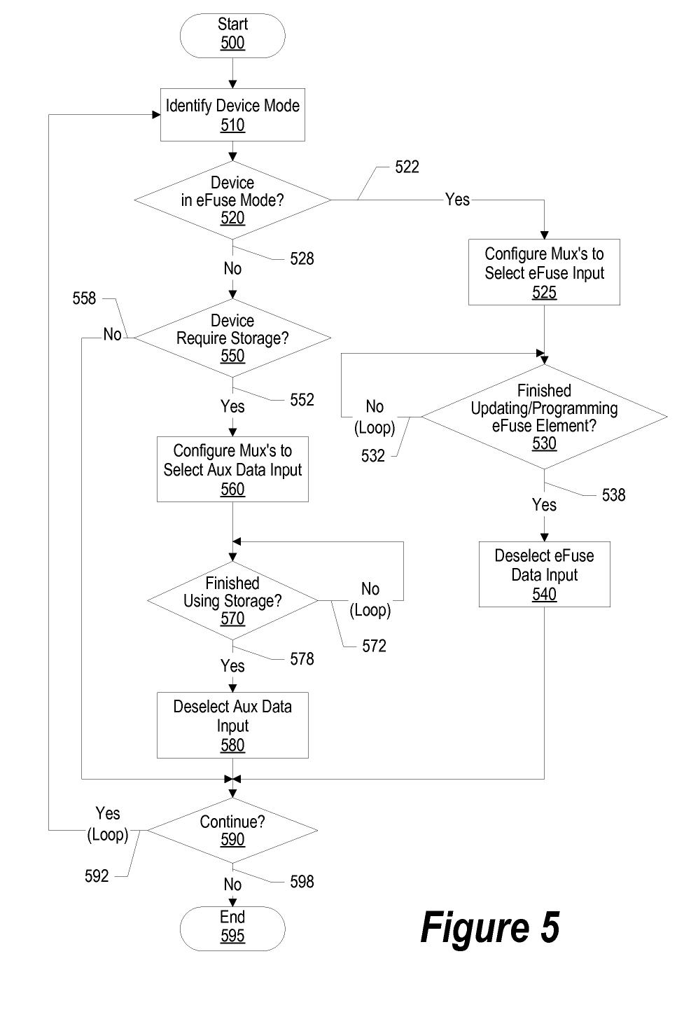

FIG. 5 is a flowchart showing steps taken in configuring multiplexers to select eFuse data or auxiliary data as inputs to provide to eFuse latches. EFuse latches provide eFuse data to an eFuse element during electronic fuse programming, and the eFuse latches store auxiliary data when they are not used to program an eFuse element. A multiplexer coupled to each eFuse latch selects between eFuse data or auxiliary data to provide to the eFuse latches.

Processing commences at 500, whereupon processing identifies a device's mode, which may be an eFuse mode or an auxiliary data mode (step 510). The eFuse mode includes times at which a device is programming an eFuse element or updating the eFuse element. The auxiliary data mode includes time at which eFuse latches are available to store auxiliary data, such as when the device is operational and not in eFuse mode.

A determination is made as to whether the device is in eFuse mode (decision 520). If the device is in eFuse mode, decision 520 branches to “Yes” branch 522 whereupon processing configures the multiplexers to select eFuse data as input to the eFuse latches (step 525). At this point, the eFuse latches may receive data from an eFuse controller, such as eFuse controller 140 shown in FIG. 1. A determination is made as to whether the eFuse controller has finished programming or updating the eFuse element through the eFuse latches (decision 530). If the eFuse controller is not finished programming or updating the eFuse element, decision 530 branches to “No” branch 532 which loops back to wait for the eFuse controller to finish programming or updating the eFuse element. This looping continues until the eFuse controller is finished programming or updating the eFuse element, at which point decision 530 branches to “Yes” branch 538 whereupon processing configures the multiplexer control to deselect the eFuse data input (step 540).

If the device is not in eFuse mode, decision 520 branches to “No” branch 528 whereupon a determination is made as to whether the device requires storage (decision 550). For example, a device may be operational and wish to store a device level configuration ring as it shifts into the device. In this example, a processor may use the device level ring information to verify configuration data content at a later time.

If the device does not require storage, decision 550 branches to “No” branch 558 bypassing auxiliary data storage steps. On the other hand, if the device does require storage, decision 550 branches to “Yes” branch 552 whereupon processing configures the multiplexers to select auxiliary data as input to the eFuse latches (step 560). At this point, a processor may store auxiliary data in the eFuse latches. A determination is made as to whether the processor is finished using the eFuse latches for storage (decision 570). In one embodiment, a processor may program the multiplexers to select auxiliary data by default until the multiplexers are instructed to select eFuse data.

If the processor is not finished using the eFuse latches for storage, decision 570 branches to “No” branch 572 which loops back to wait until the processor is finished using the eFuse latches for storage. This looping continues until the processor does not require the eFuse latches for storage, at which point decision 570 branches to “Yes” branch 578 whereupon processing configures the multiplexers to deselect the auxiliary data (step 580). In one embodiment, the multiplexers may be configured by default to select auxiliary data as input until they are configured to select eFuse data as input.

A determination is made as to whether to continue processing (decision 590). If processing should continue, decision 590 branches to “Yes” branch 592 whereupon processing loops back to monitor the device mode and configure the multiplexers accordingly. This looping continues until processing should terminate, at which point decision 590 branches to “No” branch 598 whereupon processing ends at 595.

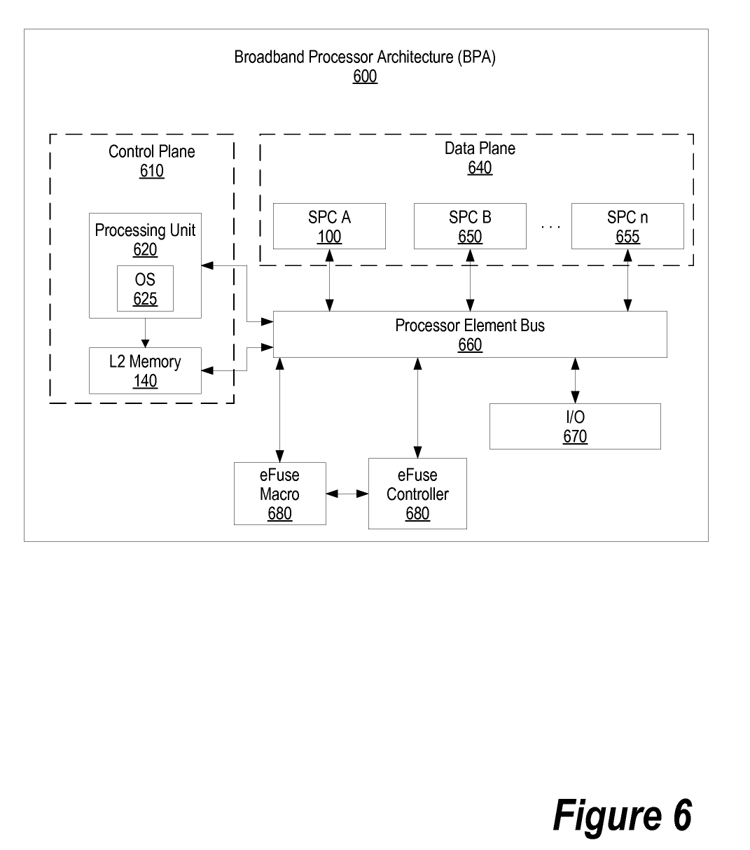

FIG. 6 is a diagram showing a block diagram of a broadband processor architecture, which is a computing device capable of implementing the present invention. BPA 600 includes a plurality of heterogeneous processors, a common memory, and a common bus. The heterogeneous processors are processors with different instruction sets that share the common memory and the common bus. For example, one of the heterogeneous processors may be a digital signal processor and the other heterogeneous processor may be a microprocessor, both sharing the same memory space.

BPA 600 sends and receives information to/from external devices through input output 670, and distributes the information to control plane 610 and data plane 640 using processor element bus 660. Control plane 610 manages BPA 600 and distributes work to data plane 640.

Control plane 610 includes processing unit 620, which runs operating system (OS) 625. For example, processing unit 620 may be a Power PC core that is embedded in BPA 600 and OS 625 may be a Linux operating system. Processing unit 620 manages a common memory map table for BPA 600. The memory map table corresponds to memory locations included in BPA 600, such as L2 memory 630 as well as non-private memory included in data plane 640.

Data plane 640 includes Synergistic Processing Complex's (SPC) 645, 650, and 655. Each SPC is used to process data information and each SPC may have different instruction sets. For example, BPA 600 may be used in a wireless communications system and each SPC may be responsible for separate processing tasks, such as modulation, chip rate processing, encoding, and network interfacing. In another example, each SPC may have identical instruction sets and may be used in parallel to perform operations benefiting from parallel processes. Each SPC includes a synergistic processing unit (SPU). An SPU is preferably a single instruction, multiple data (SIMD) processor, such as a digital signal processor, a microcontroller, a microprocessor, or a combination of these cores. In a preferred embodiment, each SPU includes a local memory, registers, four floating-point units, and four integer units. However, depending upon the processing power required, a greater or lesser number of floating points units and integer units may be employed.

SPC 645, 650, and 655 are connected to processor element bus 660, which passes information between control plane 610, data plane 640, and input/output 670. Bus 660 is an on-chip coherent multi-processor bus that passes information between I/O 670, control plane 610, and data plane 640. Input/output 670 includes flexible input-output logic, which dynamically assigns interface pins to input output controllers based upon peripheral devices that are connected to BPA 600.

Efuse macro 680 and eFuse controller 690 are connected to processor element bus 660 and provide electronic fuse capability and storage capability to broadband processor architecture 600.

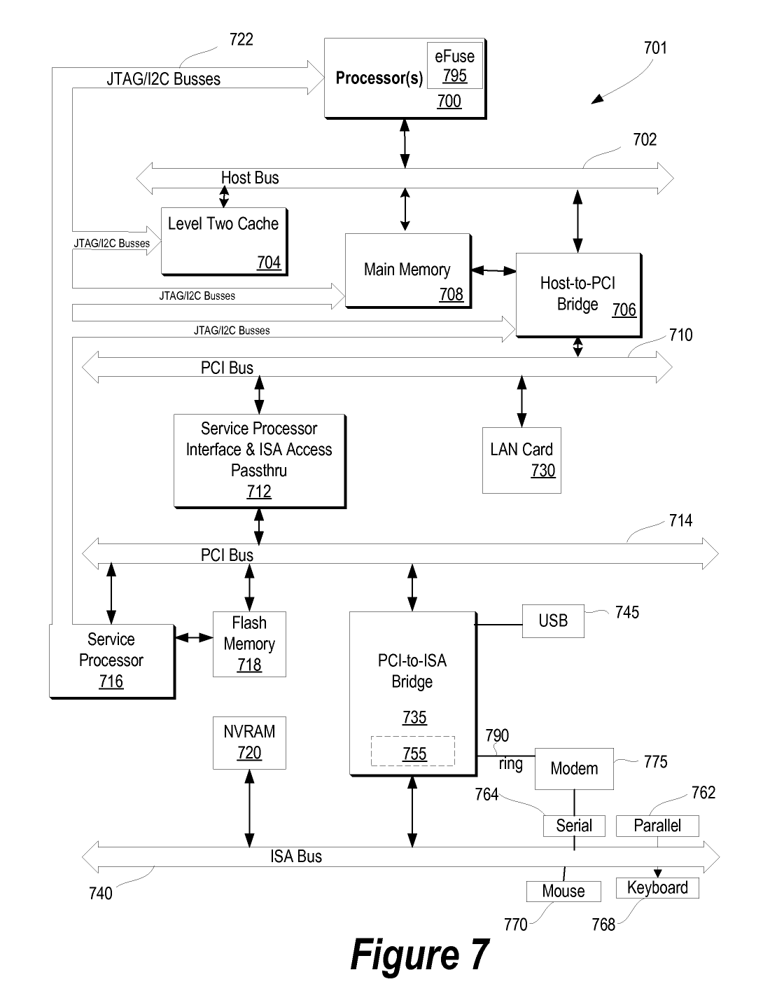

FIG. 7 illustrates information handling system 701, which is a simplified example of a computer system capable of performing the computing operations described herein. Computer system 701 includes processor 700, which is coupled to host bus 702. A level two (L2) cache memory 704 is also coupled to host bus 702. Host-to-PCI bridge 706 is coupled to main memory 708, includes cache memory and main memory control functions, and provides bus control to handle transfers among PCI bus 710, processor 700, L2 cache 704, main memory 708, and host bus 702. Main memory 708 is coupled to Host-to-PCI bridge 706 as well as host bus 702. Devices used solely by host processor(s) 700, such as LAN card 730, are coupled to PCI bus 710. Service Processor Interface and ISA Access Pass-through 712 provides an interface between PCI bus 710 and PCI bus 714. In this manner, PCI bus 714 is insulated from PCI bus 710. Devices, such as flash memory 718, are coupled to PCI bus 714. In one implementation, flash memory 718 includes BIOS code that incorporates the necessary processor executable code for a variety of low-level system functions and system boot functions.

PCI bus 714 provides an interface for a variety of devices that are shared by host processor(s) 700 and Service Processor 716 including, for example, flash memory 718. PCI-to-ISA bridge 735 provides bus control to handle transfers between PCI bus 714 and ISA bus 740, universal serial bus (USB) functionality 745, power management functionality 755, and can include other functional elements not shown, such as a real-time clock (RTC), DMA control, interrupt support, and system management bus support. Nonvolatile RAM 720 is attached to ISA Bus 740. Service Processor 716 includes JTAG and I2C busses 722 for communication with processor(s) 700 during initialization steps. JTAG/I2C busses 722 are also coupled to L2 cache 704, Host-to-PCI bridge 706, and main memory 708 providing a communications path between the processor, the Service Processor, the L2 cache, the Host-to-PCI bridge, and the main memory. Service Processor 716 also has access to system power resources for powering down information handling device 701.

Peripheral devices and input/output (I/O) devices can be attached to various interfaces (e.g., parallel interface 762, serial interface 764, keyboard interface 768, and mouse interface 770 coupled to ISA bus 740. Alternatively, many I/O devices can be accommodated by a super I/O controller (not shown) attached to ISA bus 740.

In order to attach computer system 701 to another computer system to copy files over a network, LAN card 730 is coupled to PCI bus 710. Similarly, to connect computer system 701 to an ISP to connect to the Internet using a telephone line connection, modem 775 is connected to serial port 764 and PCI-to-ISA Bridge 735.

EFuse 795 includes an eFuse macro and an eFuse controller as described herein, and provide electronic fuse capability and storage capability to computer system 701. For example, service processor 716 may send configuration data to processor(s) 700, which is stored in eFuse latches included in efuse 795.

While the computer system described in FIGS. 6 and 7 are capable of executing the processes described herein, this computer system is simply one example of a computer system. Those skilled in the art will appreciate that many other computer system designs are capable of performing the processes described herein.

One of the preferred implementations of the invention is a client application, namely, a set of instructions (program code) in a code module that may, for example, be resident in the random access memory of the computer. Until required by the computer, the set of instructions may be stored in another computer memory, for example, in a hard disk drive, or in a removable memory such as an optical disk (for eventual use in a CD ROM) or floppy disk (for eventual use in a floppy disk drive), or downloaded via the Internet or other computer network. Thus, the present invention may be implemented as a computer program product for use in a computer. In addition, although the various methods described are conveniently implemented in a general purpose computer selectively activated or reconfigured by software, one of ordinary skill in the art would also recognize that such methods may be carried out in hardware, in firmware, or in more specialized apparatus constructed to perform the required method steps.

While particular embodiments of the present invention have been shown and described, it will be obvious to those skilled in the art that, based upon the teachings herein, that changes and modifications may be made without departing from this invention and its broader aspects. Therefore, the appended claims are to encompass within their scope all such changes and modifications as are within the true spirit and scope of this invention. Furthermore, it is to be understood that the invention is solely defined by the appended claims. It will be understood by those with skill in the art that if a specific number of an introduced claim element is intended, such intent will be explicitly recited in the claim, and in the absence of such recitation no such limitation is present. For non-limiting example, as an aid to understanding, the following appended claims contain usage of the introductory phrases “at least one” and “one or more” to introduce claim elements. However, the use of such phrases should not be construed to imply that the introduction of a claim element by the indefinite articles “a” or “an” limits any particular claim containing such introduced claim element to inventions containing only one such element, even when the same claim includes the introductory phrases “one or more” or “at least one” and indefinite articles such as “a” or “an”; the same holds true for the use in the claims of definite articles.

What is claimed is:

1. A computer-implemented method comprising:
identifying a device mode corresponding to an eFuse macro, the eFuse macro including one or more eFuse latches;
determining whether the device mode is in an auxiliary data mode;
configuring, based upon the determination, one or more multiplexers corresponding to the eFuse latches to select auxiliary data as an input; and
storing the auxiliary data in the eFuse latches using the multiplexers.

2. The method of claim 1 further comprising:
detecting that the device mode is in an eFuse mode;
re-configuring, in response to the detecting, the multiplexers to select eFuse data to provide to the eFuse latches, the eFuse data including program data and control data; and
providing the eFuse data to the eFuse latches through the re-configured multiplexers.

3. The method of claim 1 further comprising:
determining whether temporary storage is required, the temporary storage corresponding to storing the auxiliary data in the eFuse latches that are also used to store eFuse data.

4. The method of claim 1 further comprising:
configuring selection logic to provide the output of the eFuse latches to a processing unit; and
providing the auxiliary data from the eFuse latches to the processing unit through the selection logic.

5. The method of claim 1 wherein the eFuse latches are selected from the group consisting of a program solution latch and a program enable/data capture latch.

6. The method of claim 1 wherein the device mode is controlled by an external test system.

7. The method of claim 1 further comprising:
wherein the method is performed using a broadband processor architecture, the broadband processor architecture including a plurality of heterogeneous processors, a common memory, and a common bus; and
wherein the plurality of heterogeneous processors use different instruction sets and share the common memory and the common bus.

8. A computer program product comprising:
a computer operable medium having computer readable code, the computer readable code being effective to:
identify a device mode corresponding to an eFuse macro, the eFuse macro including one or more eFuse latches;
determine whether the device mode is in an auxiliary data mode;
configure, based upon the determination, one or more multiplexers corresponding to the eFuse latches to select auxiliary data as an input; and
store the auxiliary data in the eFuse latches using the multiplexers.

9. The computer program product of claim 8 wherein the computer readable code is further effective to:
detect that the device mode is in an eFuse mode;
re-configure, in response to the detecting, the multiplexers to select eFuse data to provide to the eFuse latches, the eFuse data including program data and control data; and
provide the eFuse data to the eFuse latches through the re-configured multiplexers.

10. The computer program product of claim 8 wherein the computer readable code is further effective to:
determine whether temporary storage is required, the temporary storage corresponding to storing the auxiliary data in the eFuse latches that are also used to store eFuse data.

11. The computer program product of claim 8 wherein the computer readable code is further effective to:
configure selection logic to provide the output of the eFuse latches to a processing unit; and
provide the auxiliary data from the eFuse latches to the processing unit through the selection logic.

12. The computer program product of claim 8 wherein the eFuse latches are selected from the group consisting of a program solution latch and a program enable/data capture latch.

13. The computer program product of claim 8 wherein the device mode is controlled by an external test system.

14. The computer program product of claim 8 wherein the computer readable code is adapted to execute for a broadband processor architecture, the broadband processor architecture including a plurality of heterogeneous processors, a common memory, and a common bus; and
wherein the plurality of heterogeneous processors use different instruction sets and share the common memory and the common bus.

15. An information handling system comprising:
one or more processors;
a memory accessible by the processors;
one or more nonvolatile storage devices accessible by the processors; and
an auxiliary data storage tool for storing auxiliary data, the auxiliary data storage tool being effective to:
identify a device mode corresponding to an eFuse macro, the eFuse macro including one or more eFuse latches;
determine whether the device mode is in an auxiliary data mode;
configure, based upon the determination, one or more multiplexers corresponding to the eFuse latches to select the auxiliary data as an input; and
store the auxiliary data in the eFuse latches using the multiplexers.

16. The information handling system of claim 15 wherein the auxiliary data storage tool is further effective to:
detect that the device mode is in an eFuse mode;
re-configure, in response to the detecting, the multiplexers to select eFuse data to provide to the eFuse latches, the eFuse data including program data and control data; and
provide the eFuse data to the eFuse latches through the re-configured multiplexers.

17. The information handling system of claim 15 wherein the auxiliary data storage tool is further effective to:
determine whether temporary storage is required, the temporary storage corresponding to storing the auxiliary data in the eFuse latches that are also used to store eFuse data.

18. The information handling system of claim 15 wherein the auxiliary data storage tool is further effective to:
configure selection logic to provide the output of the eFuse latches to a processing unit; and
provide the auxiliary data from the eFuse latches to the processing unit through the selection logic.

19. The information handling system of claim 15 wherein the eFuse latches are selected from the group consisting of a program solution latch and a program enable/data capture latch.

20. The information handling system of claim 15 wherein the device mode is controlled by an external test system.
